(19) United States
(12) Patent Application Publication
(10) Pub. No.: US 2026/0082481 A1
(43) Pub. Date: Mar. 19, 2026

(54) SYSTEMS AND METHODS FOR IMPLEMENTING AN ELECTRICAL CIRCUIT INCLUDING AN INDUCTIVE TUNING ELEMENT

(71) Applicants: Advanced Micro Devices, Inc., Santa Clara, CA (US); ATI Technologies ULC, Markham (CA)

(72) Inventors: Fei Guo, Markham (CA); Leiline Castro Abarquez, Taipei (TW); Hui Ying Ng, Singapore (SG)

(73) Assignees: Advanced Micro Devices, Inc., Santa Clara, CA (US); ATI Technologies ULC, Markham (CA)

(21) Appl. No.: 18/176,177

(22) Filed: Feb. 28, 2023

(51) Int. Cl. H05K 1/14; H05K 1/11

(52) U.S. Cl. CPC H05K 1/141; H05K 1/111; H05K 2201/10325; H05K 2201/10666; H05K 2201/10719

(57) ABSTRACT

The disclosed electrical circuit can include a circuit connection structure and a pad provided to the circuit connection structure. The disclosed electrical circuit can additionally include an inductive tuning element provided to the circuit connection structure. The inductive tuning element can compensate parasitic capacitance of the pad. Various other methods, systems, and computer-readable media are also disclosed.

### BACKGROUND

An integrated circuit package includes a block of semiconductor material encapsulated in a supporting case that prevents physical damage and corrosion. The case, known as a package, supports the electrical contacts which connect the device to a printed circuit board. Some integrated circuits can connect to the printed circuit board by pads that can be implemented as contacts of a land grid array (LGA). Printed circuit boards can include pads such as anti-pads implemented in internal layers.

The LGA is a type of surface-mount packaging for integrated circuits (ICs) that provides a grid of contacts (e.g., pads or lands) on the underside of a package. An LGA package can be electrically connected to a printed circuit board (PCB) either by the use of a socket or by soldering directly to the board. The LGA package is notable for having pins on a socket (i.e., when a socket is used) rather than an integrated circuit.

An anti-pad in a printed circuit board (PCB) refers to a void area around a plated through hole (PTH) on an internal plane layer of the PCB. The anti-pad restricts other signal traces that should not be connected to that particular PTH. Both pads and anti-pads can exhibit parasitic capacitance that can detrimentally affect operation of the circuit in which they are implemented.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a block diagram of an example system for implementing an electrical circuit including an inductive tuning element.

FIG. 2 is a flow diagram of an example method for implementing an electrical corresponding to a land grid array including an inductive tuning element.

FIG. 3 is a perspective view of an electrical circuit model.

FIG. 4 is a top view of test structures used in tuning an inductive tuning element of an electrical circuit corresponding to a land grid array socket.

FIG. 5 is a top view of example land grid array sockets having inductive tuning elements.

FIG. 6 is a graphical representation illustrating sensitivity of inductive tuning relating to return loss.

FIG. 7 is a graphical representation illustrating sensitivity of inductive tuning relating to insertion loss.

FIG. 8 is a graphical representation of differential insertion and return losses for short and long trace structures corresponding to inductive tuning elements provided to land grid array sockets.

FIG. 9 is a graphical representation of time domain reflectrometry (TDR) analyses involving top and bottom probing of land grid array packages implementing short and long trace structures corresponding to inductive tuning elements provided to land grid array sockets.

FIG. 10 is a set of perspective views of an example system using four probes to tune an inductive tuning element of a land grid array socket.

FIG. 11 is a set of perspective views of an example system using two probes to tune an inductive tuning element of a land grid array socket.

FIG. 12 is a set of top views and a graphical representation illustrating tuning of an inductive tuning element for a short trace structure.

FIG. 13 is a set of top views and a graphical representation illustrating tuning of an inductive tuning element for a long trace structure.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for implementing an electrical circuit including an inductive tuning element. For example, pads and anti-pads of electrical circuits can exhibit parasitic capacitance, detrimentally impacting return loss of the electrical circuits. The disclosed tuning structure can improve the return loss significantly. Implementing an electrical circuit including an inductive tuning element can include performing a detailed analysis to understand the electrical characteristics of the structure. An example analysis can include performing model extraction of an electrical circuit, analyzing the model and tuning the extracted model using a lumped element to determine a target inductance, implementing a trace structure having the target inductance, and performing sensitivity analysis on the implemented trace structure. If this sensitivity analysis detects significant sensitivity, then one or more additional trace structures can be implemented and analyzed to arrive at a more reliable implementation.

In one example, an electrical circuit can include a circuit connection structure, a pad provided to the circuit connection structure and an inductive tuning element provided to the circuit connection structure and compensating parasitic capacitance of the pad.

Another example can be the previously described electrical circuit, wherein at least one of the circuit connection structure corresponds to a land grid array socket and the pad corresponds to a land grid array pad provided to the land grid array socket, or the circuit connection corresponds to a plated through hole and the pad corresponds to an anti-pad provided as a void area around the plated through hole.

Another example can be the electrical circuit of any of the previously described electrical circuits, wherein the circuit connection structure corresponds to the land grid array socket the land grid array socket has the inductive tuning element instead of a pin.

Another example can be the electrical circuit of any of the previously described electrical circuits, wherein the inductive tuning element corresponds to a trace structure exhibiting a target inductance to compensate the parasitic capacitance of the pad.

Another example can be the electrical circuit of any of the previously described electrical circuits, wherein the trace structure has a length tuned at least in part by performing model extraction of an electrical circuit model and determining the target inductance by analyzing and tuning the extracted electrical circuit model using a lumped element.

Another example can be the electrical circuit of any of the previously described electrical circuits, wherein the length is further tuned at least in part by implementing the target inductance using the trace structure.

Another example can be the electrical circuit of any of the previously described electrical circuits, wherein the length is further tuned at least in part by performing sensitivity analysis on the trace structure.

Another example can be the electrical circuit of any of the previously described electrical circuits, wherein the length is further tuned at least in part by implementing the target inductance using an additional trace structure and performing sensitivity analysis on the additional trace structure.

Another example can be the electrical circuit of any of the previously described electrical circuits, wherein the inductive tuning element corresponds to a length of wire.

In one example, a system can include at least one physical processor and physical memory comprising computer-executable instructions that, when executed by the physical processor, cause the physical processor to perform model extraction of an electrical circuit model, determine a target inductance of an inductive tuning element to compensate parasitic capacitance of a pad of the electrical circuit model by analyzing and tuning the extracted electrical circuit model using a lumped element, perform sensitivity analysis on a trace structure implementing the target inductance.

Another example can be the system of the previously described example system, wherein the computer-executable instructions further cause the at least one physical processor to perform sensitivity analysis on an additional trace structure implementing the target inductance.

Another example can be the system of any of the previously described example systems, wherein the inductive tuning element corresponds to the trace structure and has a length selected to cause the trace structure to exhibit the target inductance.

Another example can be the system of any of the previously described example systems, wherein the inductive tuning element corresponds to a length of wire.

Another example can be the system of any of the previously described example systems, wherein the inductive tuning element is embedded in at least one of a land grid array package or a printed circuit board.

Another example can be the system of any of the previously described example systems, wherein the inductive tuning element is embedded in the land grid array package and a socket of the land grid array package has the inductive tuning element instead of a pin.

In one example, a computer-implemented method can include performing, by at least one processor, model extraction of an electrical circuit model, determining, by the at least one processor, a target inductance of an inductive tuning element to compensate parasitic capacitance of a pad of the electrical circuit model by analyzing and tuning the extracted electrical circuit model using a lumped element, and performing, by the at least one processor, sensitivity analysis on a trace structure implementing the target inductance.

Another example can be the method of the previously described example method, further comprising performing, by the at least one processor, sensitivity analysis on an additional trace structure implementing the target inductance.

Another example can be the method of any of the previously described example methods, wherein the inductive tuning element corresponds to the trace structure and has a length selected to cause the trace structure to exhibit the target inductance.

Another example can be the method of any of the previously described example methods, wherein the inductive tuning element corresponds to a length of wire.

Another example can be the method of any of the previously described example methods, wherein the inductive tuning element is embedded in at least one of a land grid array package or a printed circuit board.

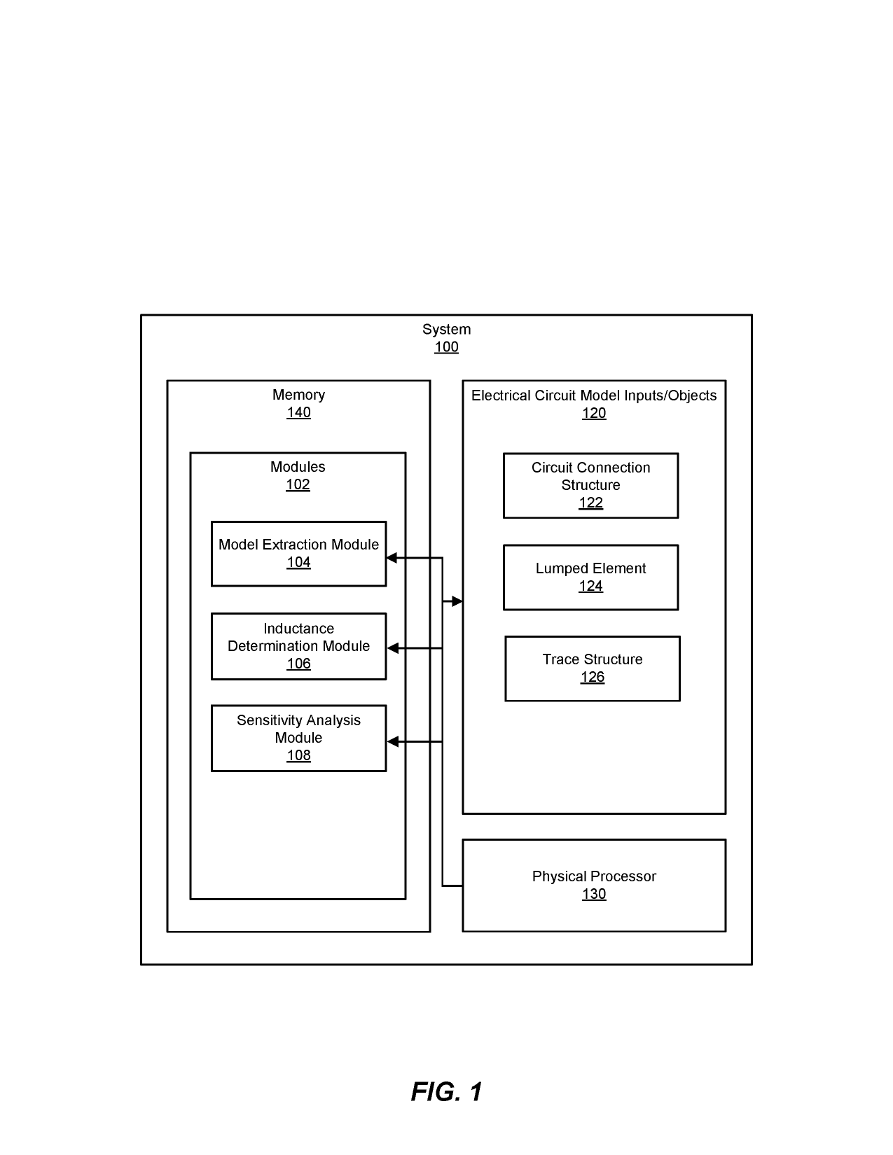

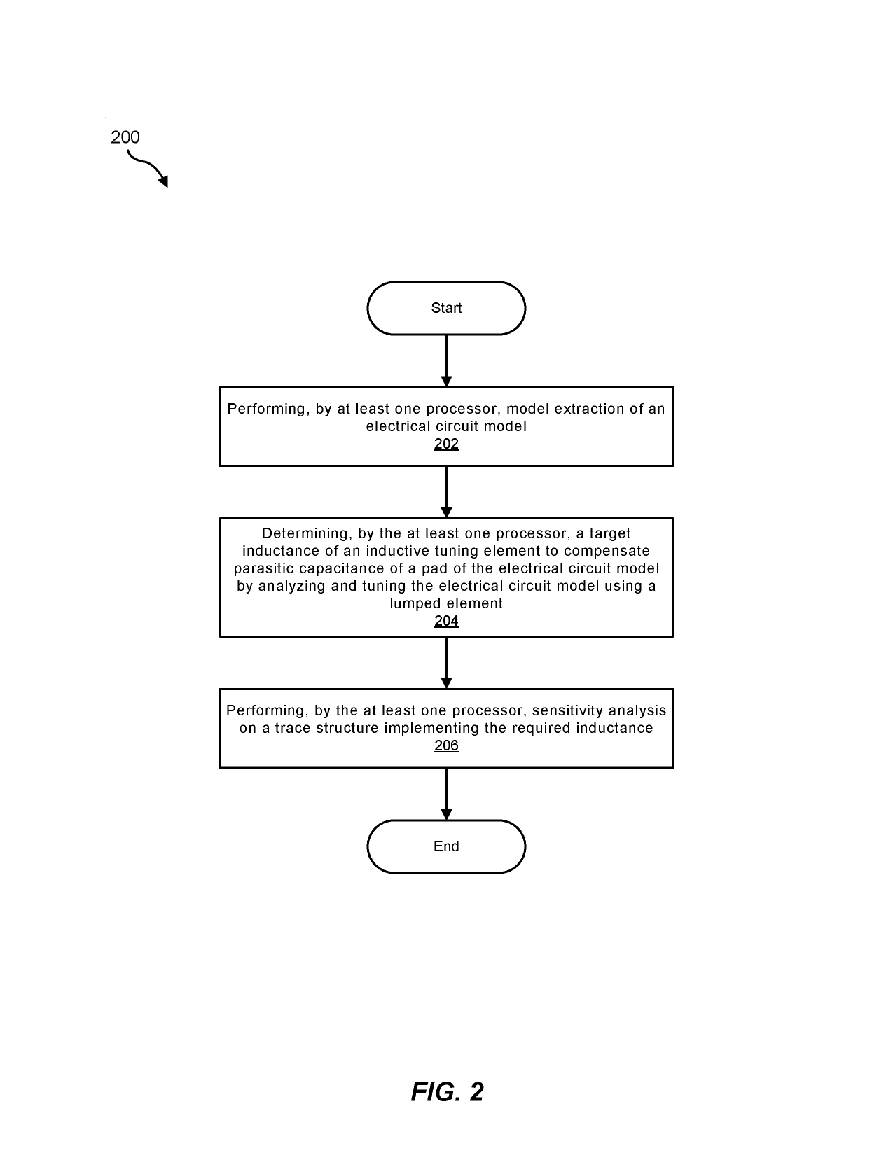

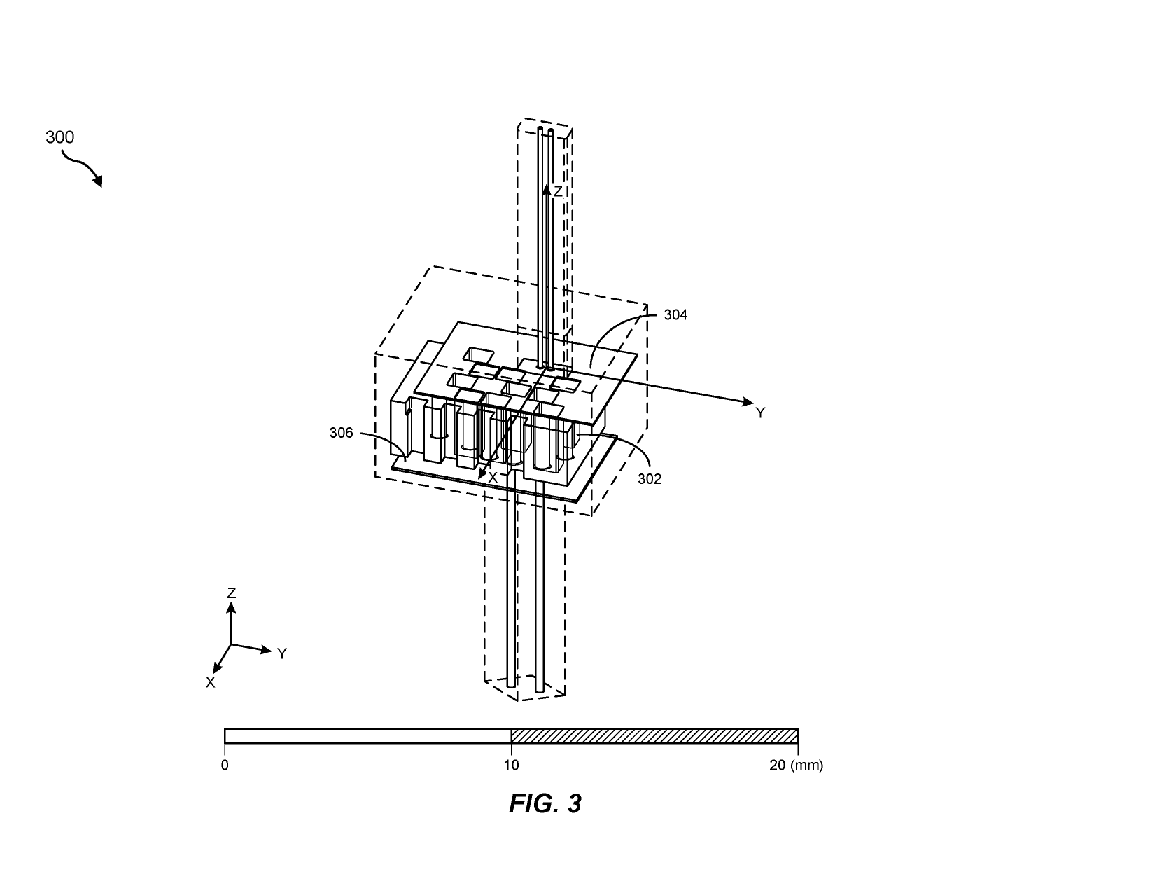

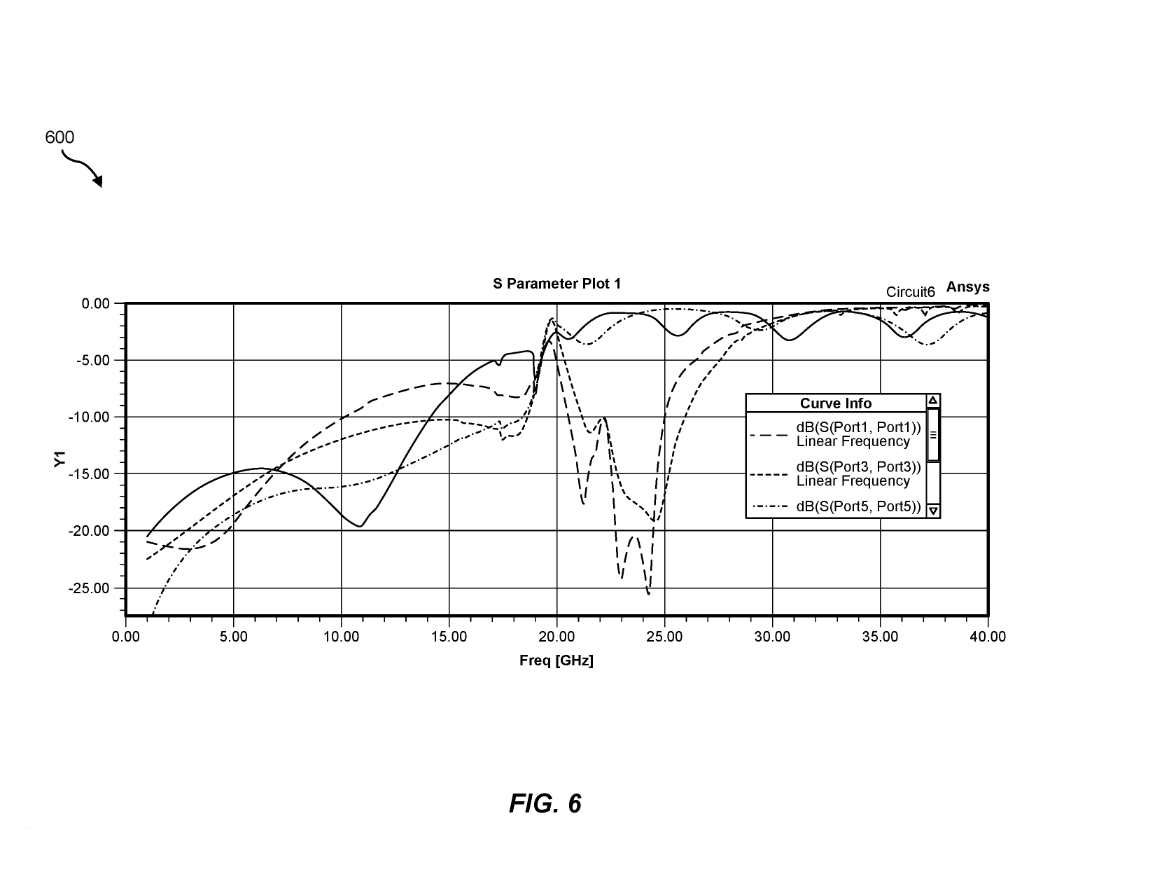

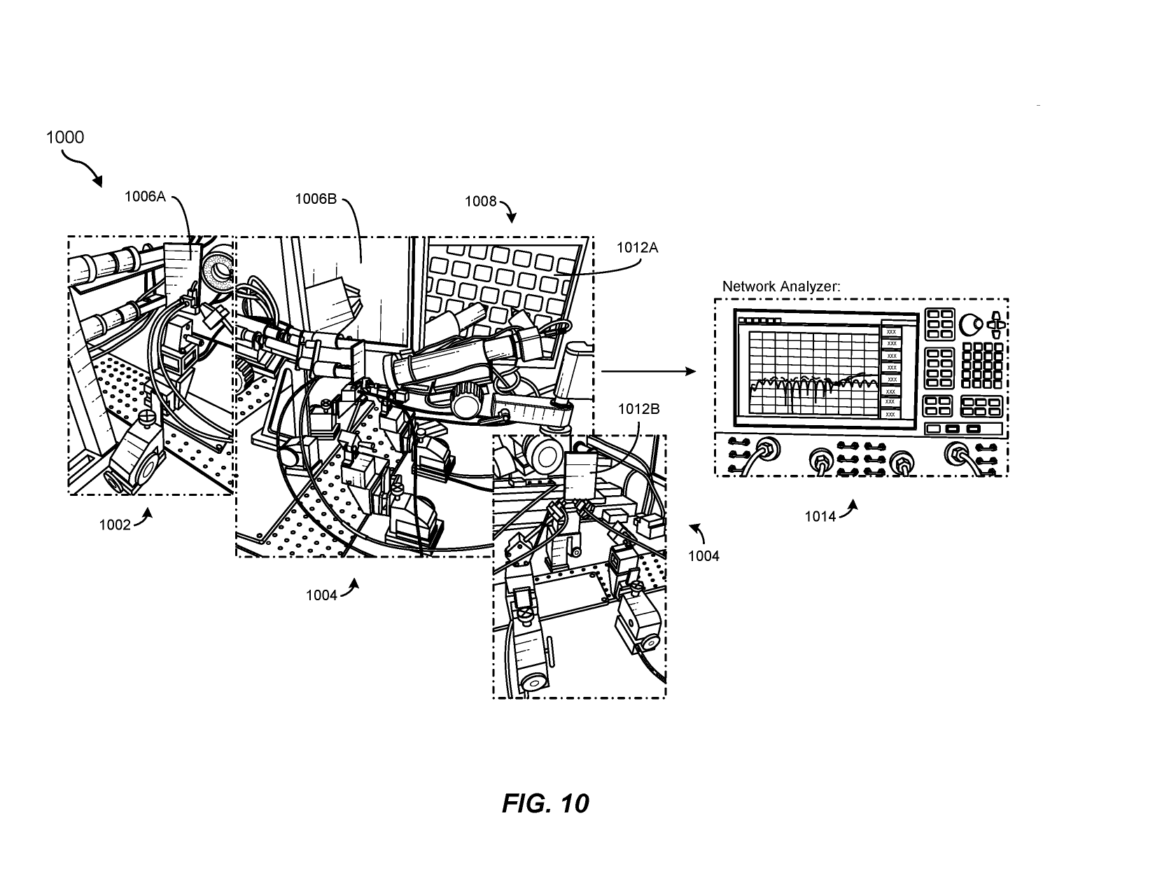

The following will provide, with reference to FIG. 1, detailed descriptions of an example system for implementing an electrical circuit including an inductive tuning element. Detailed descriptions of corresponding computer-implemented methods will also be provided in connection with FIG. 2. In addition, detailed descriptions of example land grid array packages, sockets, and inductive tuning elements will be provided in connection with FIGS. 3-5. Further, detailed descriptions of inductive tuning sensitivities and analyses will be provided in connection with FIGS. 6 -9. Further, detailed descriptions of testing equipment and procedures for tuning an inductive tuning element will be provided in connection with FIGS. 10-13.

FIG. 1 is a block diagram of an example system 100 for implementing an electrical circuit including an inductive tuning element. As illustrated in this figure, example system 100 can include one or more modules 102 for performing one or more tasks. As will be explained in greater detail below, modules 102 can include a model extraction module 104, an inductance determination module 106, and a sensitivity analysis module 108. Although illustrated as separate elements, one or more of modules 102 in FIG. 1 can represent portions of a single module or application.

In certain implementations, one or more of modules 102 in FIG. 1 can represent one or more software applications or programs that, when executed by a computing device, can cause the computing device to perform one or more tasks. For example, and as will be described in greater detail below, one or more of modules 102 can represent modules stored and configured to run on one or more computing devices. One or more of modules 102 in FIG. 1 can also represent all or portions of one or more special-purpose computers configured to perform one or more tasks.

As illustrated in FIG. 1, example system 100 can also include one or more memory devices, such as memory 140. Memory 140 generally represents any type or form of volatile or non-volatile storage device or medium capable of storing data and/or computer-readable instructions. In one example, memory 140 can store, load, and/or maintain one or more of modules 102. Examples of memory 140 include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

As illustrated in FIG. 1, example system 100 can also include one or more physical processors, such as physical processor 130. Physical processor 130 generally represents any type or form of hardware-implemented processing unit capable of interpreting and/or executing computer-readable instructions. In one example, physical processor 130 can access and/or modify one or more of modules 102 stored in memory 140. Additionally or alternatively, physical processor 130 can execute one or more of modules 102 to facilitate implementing an electrical circuit including an inductive tuning element. Examples of physical processor 130 include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

As illustrated in FIG. 1, example system 100 can also include one or more inputs and/or objects, such as electrical circuit model inputs/objects 120. Electrical circuit model inputs/objects 120 generally represents any type or form of data storage, processing circuitry, signal lines, data inputs, sensory signals, laboratory test equipment, etc. In one example, electrical circuit model inputs/objects 120 can include computer models of electrical circuit elements and/or physical electronic circuit elements. Examples of electrical circuit model inputs/objects 120 include, without limitation, circuit connection structure 122, lumped element 124, and trace structure 126.

Many other devices or subsystems can be connected to system 100 in FIG. 1. Conversely, all of the components and devices illustrated in FIG. 1 need not be present to practice the implementations described and/or illustrated herein. The devices and subsystems referenced above can also be interconnected in different ways from that shown in FIG. 1. System 100 can also employ any number of software, firmware, and/or hardware configurations. For example, one or more of the example implementations disclosed herein can be encoded as a computer program (also referred to as computer software, software applications, computer-readable instructions, and/or computer control logic) on a computer-readable medium.

The term “computer-readable medium,” as used herein, generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

FIG. 2 is a flow diagram of an example computer-implemented method 200 for implementing an electrical circuit including an inductive tuning element. The steps shown in FIG. 2 can be performed by any suitable computer-executable code and/or computing system, including system 100 in FIG. 1 and/or variations or combinations of one or more of the same. In one example, each of the steps shown in FIG. 2 can represent an algorithm whose structure includes and/or is represented by multiple sub-steps, examples of which will be provided in greater detail below.

As illustrated in FIG. 2, at step 202 one or more of the systems described herein can perform model extraction. For example, model extraction module 104 can perform, by at least one processor, model extraction of an electrical circuit socket model.

The term “model extraction,” as used herein, can generally refer to the translation of an integrated circuit layout back into an electrical circuit (e.g., netlist) it is intended to represent. For example, and without limitation, an extracted electrical circuit model can be used for various purposes including circuit simulation, static timing analysis, signal integrity, power analysis and optimization, and logic to layout comparison. Each of these functions can require a slightly different representation of the circuit, and multiple layout extractions can be used in some circumstances. In addition, postprocessing can convert a device-level circuit into a purely digital circuit.

The term “land grid array socket,” as used herein, can generally refer to an electrical component of a land grid array package that provides compressive electrical interconnect between a printed circuit board (PCB) and a processor. For example, and without limitation, a land grid array socket can offer a more durable CPU as the contact pins are on the motherboard socket. In contrast, a pin grid array (PGA) socket offers a more durable motherboard as the pins are on the processor. LGA pins are smaller than PGA pins and hence, the LGA socket offers more space efficiency.

The systems described herein can perform step 202 in a variety of ways. In one example, model extraction module 104 can obtain simulations and measurements with a test fixture (e.g., including motherboard transmission lines and elements of circuit connection structure 122). For example, model extraction module 104 can obtain insertion and/or return loss measurements from probes generating measurement signals from a tuning test structure that includes the electrical circuit (e.g., a LGA package, a PCB, etc.). In another example, model extraction module 104 can establish a lumped-circuit model (e.g., lumped element 124) from one or more geometries of simulated circuit components. In other examples, model extraction module 104 can employ any other techniques for modeling semiconductor packages and package elements may be employed.

At step 204, one or more of the systems described herein can determine a target inductance. For example, inductance determination module 106 can determine, by the at least one processor, a target inductance of an inductive tuning element to compensate parasitic capacitance of a pad of the electrical circuit model by analyzing and tuning the electrical circuit model using a lumped element.

The term “target inductance,” as used herein, can generally refer to a characteristic of an inductive tuning element provided to a circuit connection structure (e.g., a LGA socket and/or PTH) that compensates parasitic capacitance of a pad (e.g, land) provided to the circuit connection structure. For example, and without limitation, target inductance can refer to a ratio of induced voltage to a rate of change of current causing it, a length of a trace element (e.g., loop of wire), etc.

The term “parasitic capacitance,” as used herein, can generally refer to an unavoidable capacitance that exists between the parts of an electronic component or circuit because of their proximity to each other. For example, and without limitation, parasitic capacitance can refer to internal capacitance of any practical circuit element, such as an inductor, diode, transistor, etc. Internal capacitance can cause the behavior of circuit elements to depart from that of ideal circuit elements.

The term “lumped element,” as used herein, can generally refer to an element that is smaller than the wavelength of applied signals so that the effects of wave propagation can be neglected; physical dimensions of lumped elements allow the assumption that signals do not vary over the interconnects interfacing them. For example, and without limitation, the lumped-element model of electronic circuits makes the simplifying assumption that the attributes of the circuit, resistance, capacitance, inductance, and gain, are concentrated into idealized electrical components (e.g., resistors, capacitors, inductors, etc.) joined by a network of perfectly conducting wires.

The term “pad,” as used herein, can generally refer to an electrical contact. For example, and without limitation, the pad can be an LGA pad provided to a LGA socket, an anit-pad provided to a PTH, etc. The LGA pad, for example, can be an electrical contact in a grid of such contacts in a land grid array package. For example, and without limitation, an LGA pad can refer to one of the “lands” of a land grid array package that connects to a PCB with the aid of solder paste that is typically printed on the PCB.

The systems described herein can perform step 204 in a variety of ways. In one example, inductance determination module 106 can compare measurements (e.g., insertion loss and/or return loss) from a test structure lacking an inductive tuning element to one or more characteristics (e.g., insertion loss and/or return loss) of the lumped element. Such a procedure can determine parasitic capacitance of the pad. Thus, inductance determination module 106 can determine an amount of inductance (e.g., equal and opposite to the parasitic capacitance) that effectively compensates this parasitic capacitance as the target inductance. The target inductance may additionally equate to a length of a trace structure (e.g., loop of wire) that serves as the inductive tuning element.

At step 206, one or more of the systems described herein can perform sensitivity analysis. For example, sensitivity analysis module 108 can perform, by the at least one processor, sensitivity analysis on a trace structure implementing the target inductance.

The term “sensitivity analysis,” as used herein, can generally refer to an analysis that determines how different values of an independent variable affect a particular dependent variable under a given set of assumptions. For example, and without limitation, a sensitivity analysis can include comparing measurements of characteristics (e.g., insertion loss, return loss, etc.) of electrical circuits that do and do not include an inductive tuning element (e.g., trace structure).

The term “trace structure,” as used herein, can generally refer to an electrically conductive circuit element. For example, and without limitation, trace structure can refer to a length of wire, a signal trace, a circuit trace, a length of copper foil, etc.

The systems described herein can perform step 206 in a variety of ways. In one example, sensitivity analysis module 108 can compare measurements from a test structure lacking an inductive tuning element to measurements from a test structure including a trace structure (i.e., length of wire) having a length selected to produce the target inductance. Alternatively or additionally, sensitivity analysis module 108 can compare measurements from the test structure including the trace structure (i.e., length of wire) having the length selected to produce the target inductance to one or more characteristics of the lumped element. If the sensitivity analysis demonstrates significant sensitivity (i.e., insertion loss and/or return loss), then an additional trace structure (e.g., a different trace structure that replaces the previous trace structure) can be implemented and sensitivity analysis module 108 can perform the sensitivity analysis again. This process can be repeated until sensitivity analysis module 108 attains an acceptable trace structure. This trace structure can correspond to the inductive tuning element and be embedded in a LGA package and/or PCB.

Referring to FIG. 3, an electrical circuit model 300 can include inputs and/or objects that model an electrical circuit. In one example, electrical circuit model 300 can model an LGA socket including one or more sockets 302 extending between an upper plate 304 and a lower plate 306. Model 300 can be a translation of one or more land grid array package components into an electrical circuit. Model 300 can simulate an ideal circuit (e.g., lumped element) and used for comparing characteristics (e.g., insertion loss, return loss, etc.) of the ideal circuit to those of a test circuit.

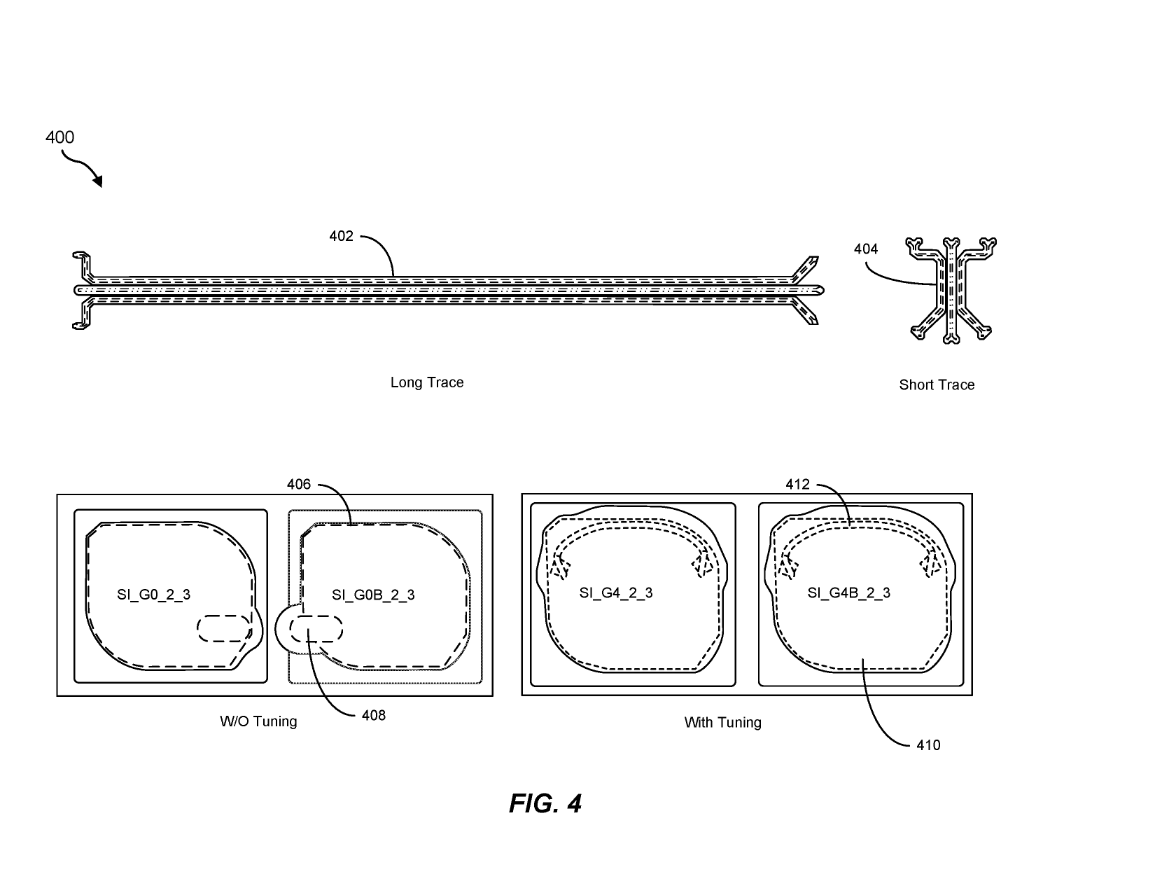

Referring to FIG. 4, test structures 400 used in tuning an inductive tuning element of an electrical circuit, such as a LGA socket, can include long and short trace structures 402 and 404. In contrast to land grid array sockets 406 that have pins 408, land grid array sockets 410 can have trace structures 412 that serve as inductive tuning elements. The lengths of these trace structures 412 can be selected to tune the amount of inductance provided to compensate parasitic capacitance of the land grid array pads.

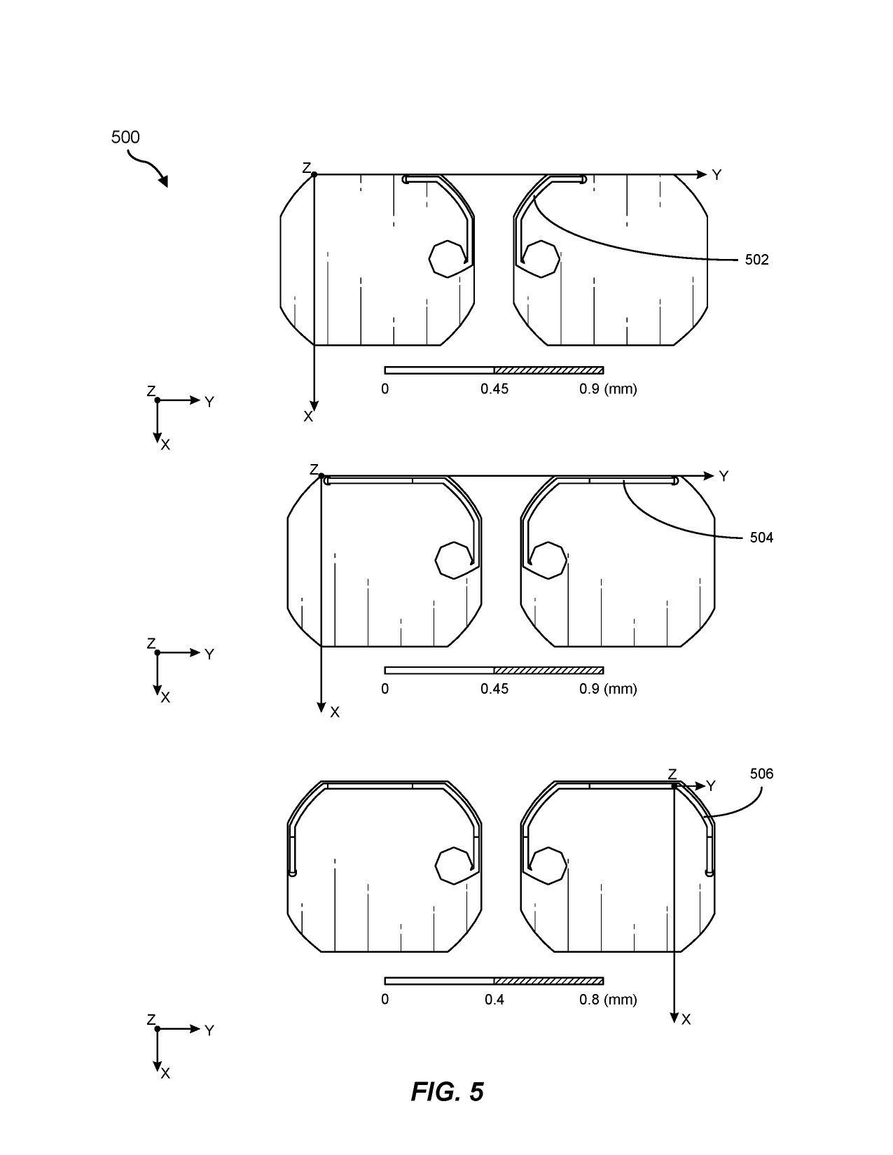

Referring to FIG. 5, example land grid array sockets 500 can have inductive tuning elements 502-506 of various lengths. Inductive tuning elements 502-506 can be provided to sockets 500 and correspond to trace structures (e.g., loops of wire). Different lengths of inductive tuning elements 502-506 can result in larger and smaller amounts of inductance that compensates parasitic capacitance of pads provided to sockets 500. For example, a longer loop of wire can exhibit a greater amount of inductance than a shorter loop of wire. Inductive tuning elements 502-506 can be provided at a top of a socket and/or embedded in a land grid array package. Inductive tuning elements 502-506 can be used instead of pins and can be connected to a processor with the aid of solder.

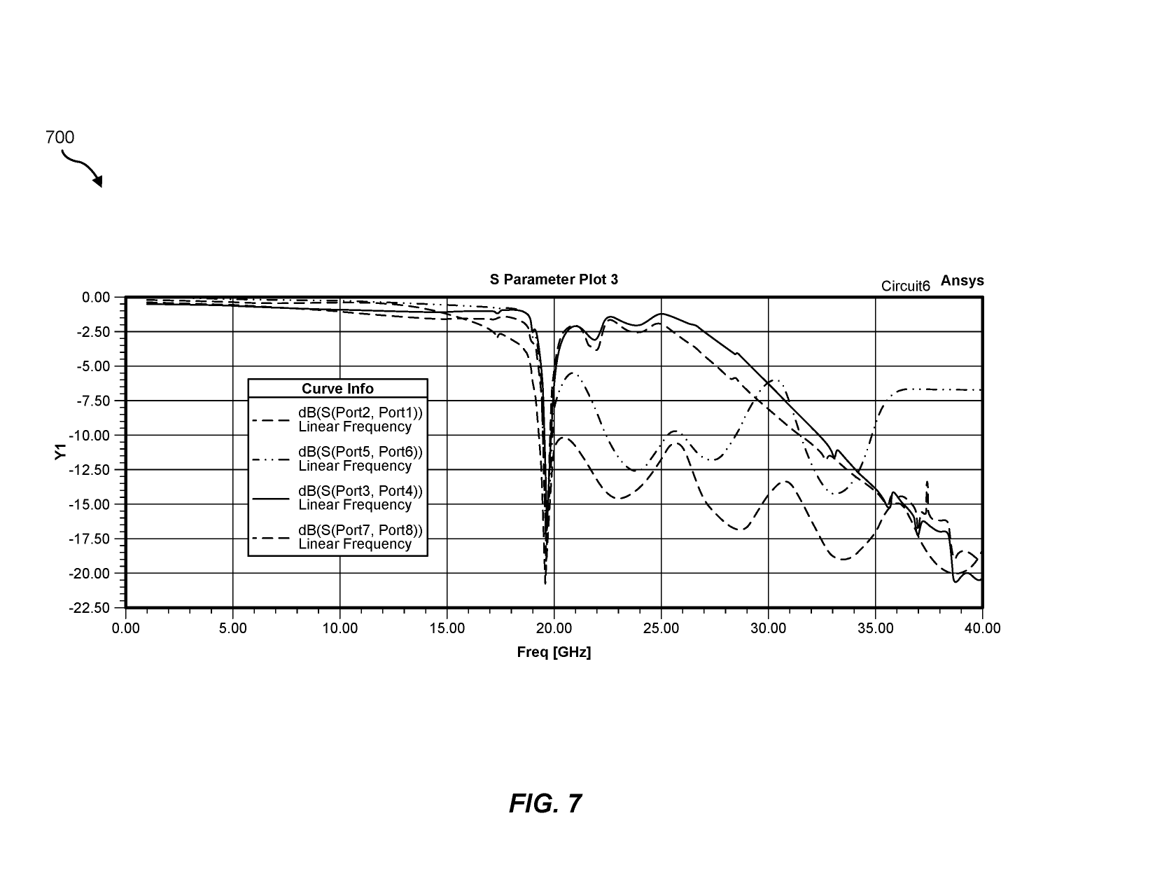

Referring generally to FIGS. 6 and 7, graphs 600 and 700 demonstrate sensitivity of inductive tuning. For example, graph 600 demonstrates sensitivity S of inductive tuning on return loss by comparing an original return loss sensitivity parameter curve without tuning to parameter curves for tuning using inductive tuning elements of different lengths. Thus, return loss can be greatly improved by using an inductive tuning element of a length that can be determined through simulation and confirmed by sensitivity analysis. Also, graph 700 demonstrates sensitivity of inductive tuning on insertion loss by comparing an original insertion loss sensitivity parameter curve without tuning to parameter curves for tuning using inductive tuning elements of different lengths. Thus, insertion loss can also be improved by using an inductive tuning element of a length that can be determined through simulation and confirmed by sensitivity analysis. Additionally, in cases where insertion loss cannot be improved, an inductive tuning element can still be determined that improves return loss without negatively impacting insertion loss to an unacceptable degree.

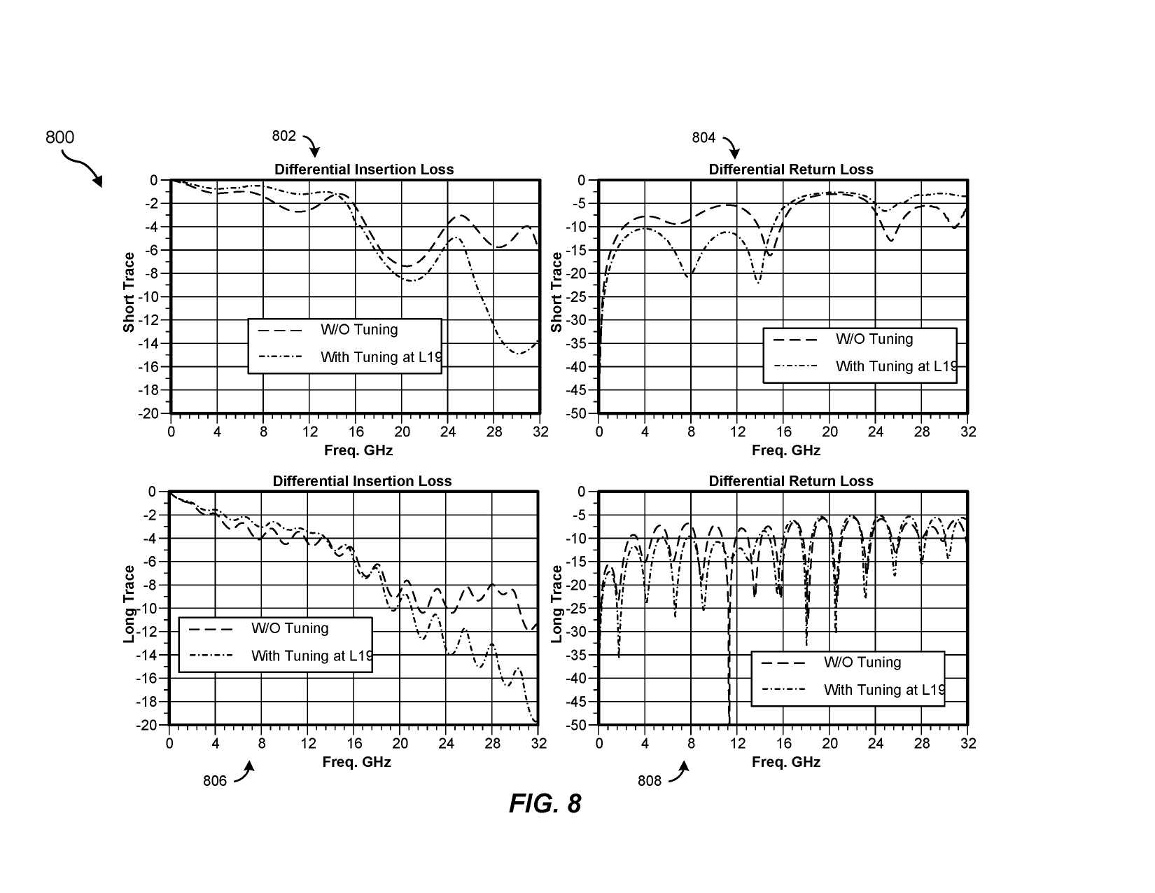

Referring to FIG. 8, graphs 800 demonstrate that differential losses (e.g., using time domain reflectrometry (TDR)) can also be analyzed. For example, graphs 802 and 804 respectively depict differential insertion loss and differential return loss when a short trace is used as the inductive tuning element compared to no inductive tuning element. Similarly, graphs 804 and 806 respectively depict differential insertion loss and differential return loss when a long trace is used as the inductive tuning element compared to no inductive tuning element.

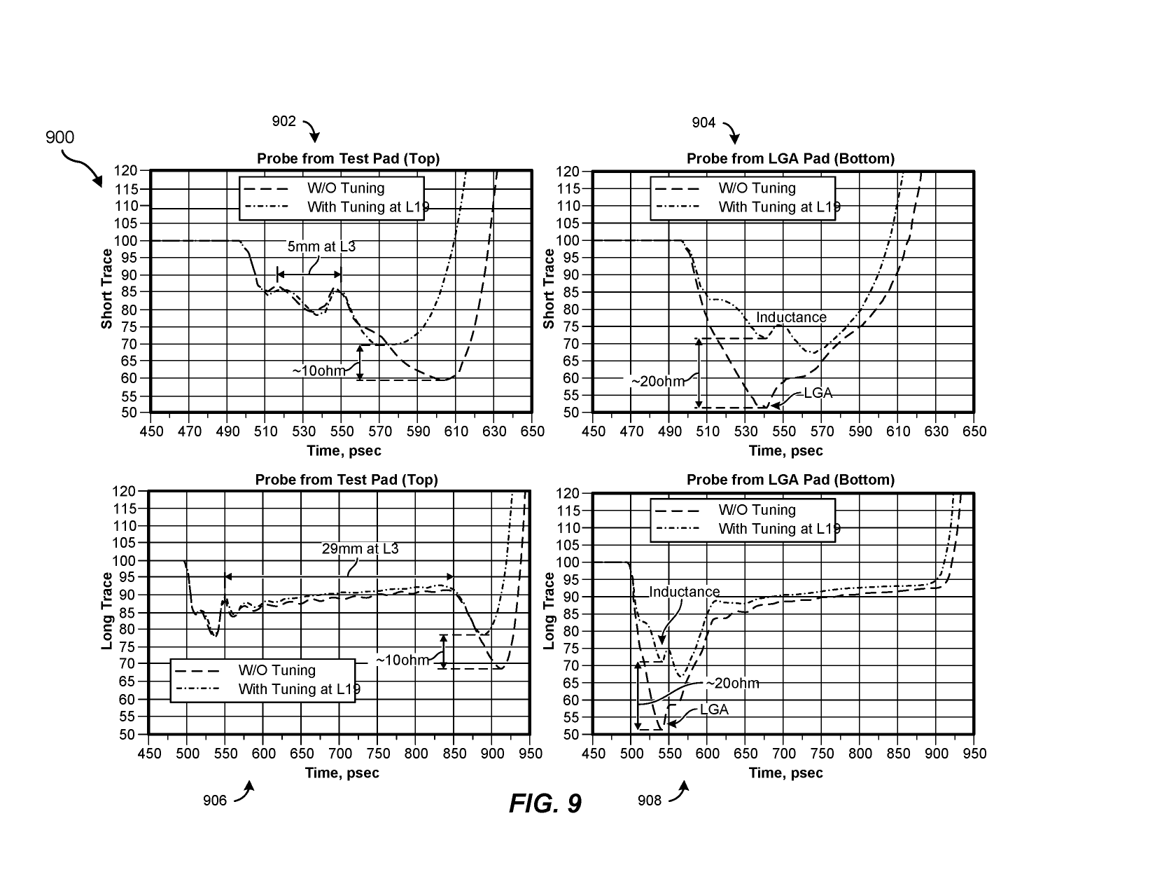

FIG. 9 is a graphical representation of time domain reflectrometry (TDR) analyses 900 involving top and bottom probing of land grid array packages implementing short and long trace structures corresponding to inductive tuning elements provided to land grid array sockets. For example, graphs 902 and 904 respectively depict TDR measured from top and bottom sides of a land grid array test pad when a short trace is used as the inductive tuning element compared to no inductive tuning element. Similarly, graphs 904 and 906 respectively depict TDR measured from top and bottom sides of a land grid array test pad when a long trace is used as the inductive tuning element compared to no inductive tuning element. As shown, these analyses indicate a 10 decibel improvement in TDR for top side measurements resulting from use of an inductive tuning element and a 20 decibel improvement in TDR for bottom side measurements resulting from use of an inductive tuning element.

Referring to FIG. 10, an example system 1000 can use four probes to tune an inductive tuning element of a land grid array socket. For example, at 1002 and 1004, system 1000 can take measurements using two probes for a top side 1006A and 1006B of a land grid array package. Similarly, at 1008 and 1010, system 1000 can take measurements using two more probes for a bottom side 1012A and 1012B of the land grid array package. System 1000 can analyze the measurements using a network analyzer 1014, which can output results of the analysis on an active display. These analyses can entail differential analyses as detailed above in connection with FIG. 8.

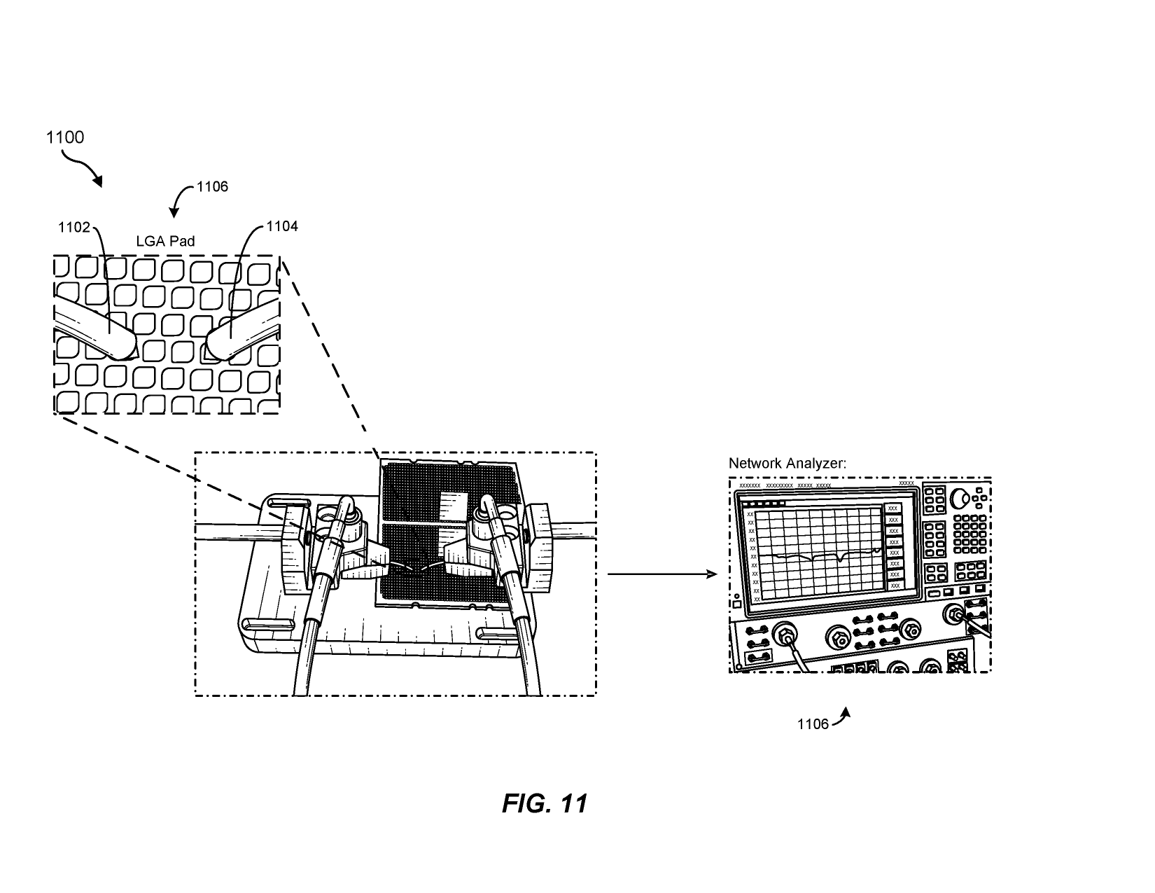

Referring to FIG. 11, another example system 1100 can use two probes to tune an inductive tuning element of a land grid array socket. For example, system 1100 can use probes 1102 and 1104 to take measurements from pads on a bottom side of a land grid array package 1106. Like system 1000 (FIG. 10), system 1100 can analyze the measurements using a network analyzer 1108, which can output results of the analysis on an active display. However, the analyses performed by analyzer 1108 can entail TDR analyses as detailed above in connection with FIG. 9.

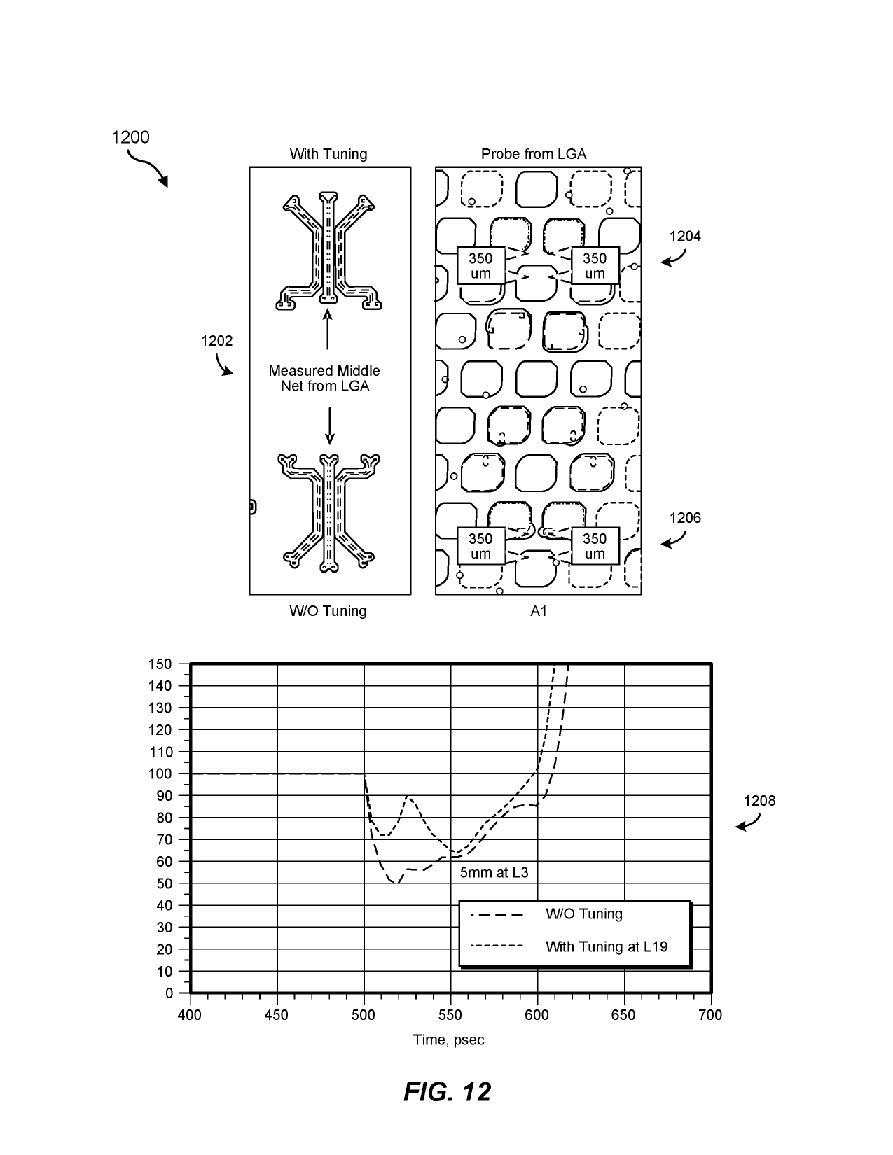

Referring to FIG. 12, tuning 1200 of an inductive tuning element corresponding to a short trace structure can be performed using, for example, the system detailed above in connection with FIG. 11. Probes can be used to take measurements at middle net 1202 from a land grid array test pad for sockets 1204 having inductive tuning elements and sockets 1206 having pins (e.g., without tuning). TDR analysis results 1208 can be displayed, stored, and/or utilized to tune the inductive tuning element for production and/or further analysis.

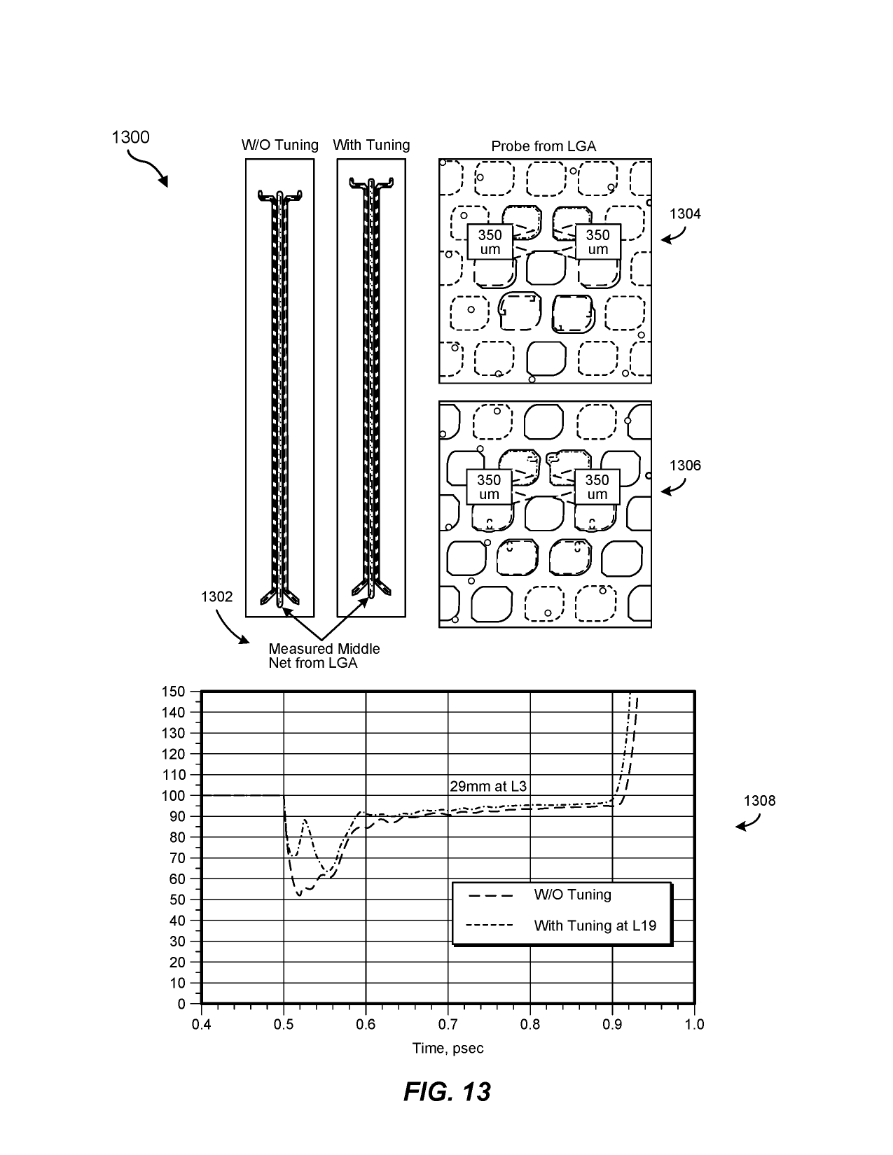

Referring to FIG. 13, tuning 1300 of an inductive tuning element corresponding to a long trace structure can be performed using, for example, the system detailed above in connection with FIG. 11. Probes can be used to take measurements at middle net 1302 from a land grid array test pad for sockets 1304 having inductive tuning elements and sockets 1306 having pins (e.g., without tuning). TDR analysis results 1308 can be displayed, stored, and/or utilized to tune the inductive tuning element for production and/or further analysis.

As set forth above, the disclosed tuning structure is capable of significantly improving return loss by compensating the excessive parasitic capacitance from a pad of an electrical circuit, such as a LGA pad or an anti-pad. The implementation can be a length of wire with target inductance. For example, instead of a socket pin, the disclosed LGA socket can have a loop of wire embedded in the socket package and the disclosed PCB can have a loop of wire embedded in the PCB package. In some examples, implementing electrical circuit including an inductive tuning element can include performing a detailed analysis to understand the electrical characteristics of the structure. An example analysis can include performing model extraction of the electrical circuit, analyzing the model and tuning the extracted model using a lumped element to determine a target inductance, implementing a trace structure having the target inductance, and performing sensitivity analysis on the implemented trace structure. If this sensitivity analysis detects significant sensitivity, then one or more additional trace structures can be implemented and analyzed to arrive at a more reliable implementation.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

In some examples, all or a portion of example system 100 in FIG. 1 can represent portions of a cloud-computing or network-based environment. Cloud-computing environments can provide various services and applications via the Internet. These cloud-based services (e.g., software as a service, platform as a service, infrastructure as a service, etc.) can be accessible through a web browser or other remote interface. Various functions described herein can be provided through a remote desktop environment or any other cloud-based computing environment.

In various implementations, all or a portion of example system 100 in FIG. 1 can facilitate multi-tenancy within a cloud-based computing environment. In other words, the modules described herein can configure a computing system (e.g., a server) to facilitate multi-tenancy for one or more of the functions described herein. For example, one or more of the modules described herein can program a server to enable two or more clients (e.g., customers) to share an application that is running on the server. A server programmed in this manner can share an application, operating system, processing system, and/or storage system among multiple customers (i.e., tenants). One or more of the modules described herein can also partition data and/or configuration information of a multi-tenant application for each customer such that one customer cannot access data and/or configuration information of another customer.

According to various implementations, all or a portion of example system 100 in FIG. 1 can be implemented within a virtual environment. For example, the modules and/or data described herein can reside and/or execute within a virtual machine. As used herein, the term “virtual machine” generally refers to any operating system environment that is abstracted from computing hardware by a virtual machine manager (e.g., a hypervisor).

In some examples, all or a portion of example system 100 in FIG. 1 can represent portions of a mobile computing environment. Mobile computing environments can be implemented by a wide range of mobile computing devices, including mobile phones, tablet computers, e-book readers, personal digital assistants, wearable computing devices (e.g., computing devices with a head-mounted display, smartwatches, etc.), variations or combinations of one or more of the same, or any other suitable mobile computing devices. In some examples, mobile computing environments can have one or more distinct features, including, for example, reliance on battery power, presenting only one foreground application at any given time, remote management features, touchscreen features, location and movement data (e.g., provided by Global Positioning Systems, gyroscopes, accelerometers, etc.), restricted platforms that restrict modifications to system-level configurations and/or that limit the ability of third-party software to inspect the behavior of other applications, controls to restrict the installation of applications (e.g., to only originate from approved application stores), etc. Various functions described herein can be provided for a mobile computing environment and/or can interact with a mobile computing environment.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An electrical circuit, comprising:
a circuit connection structure;
a pad provided to the circuit connection structure; and
an inductive tuning element provided to the circuit connection structure and compensating parasitic capacitance of the pad.

2. The electrical circuit of claim 1, wherein at least one of:
the circuit connection structure corresponds to a land grid array socket and the pad corresponds to a land grid array pad provided to the land grid array socket; or
the circuit connection corresponds to a plated through hole and the pad corresponds to an anti-pad provided as a void area around the plated through hole.

3. The electrical circuit of claim 2, wherein the circuit connection structure corresponds to the land grid array socket the land grid array socket has the inductive tuning element instead of a pin.

4. The electrical circuit of claim 1, wherein the inductive tuning element corresponds to a trace structure exhibiting a target inductance to compensate the parasitic capacitance of the pad.

5. The electrical circuit of claim 4, wherein the trace structure has a length tuned at least in part by:
performing model extraction of an electrical circuit model; and
determining the target inductance by analyzing and tuning the extracted electrical circuit model using a lumped element.

6. The electrical circuit of claim 5, wherein the length is further tuned at least in part by implementing the target inductance using the trace structure.

7. The electrical circuit of claim 6, wherein the length is further tuned at least in part by performing sensitivity analysis on the trace structure.

8. The electrical circuit of claim 7, wherein the length is further tuned at least in part by implementing the target inductance using an additional trace structure and performing sensitivity analysis on the additional trace structure.

9. The electrical circuit of claim 1, wherein the inductive tuning element corresponds to a length of wire.

10. A system comprising:
at least one physical processor; and
physical memory comprising computer-executable instructions that, when executed by the at least one physical processor, cause the at least one physical processor to:
perform model extraction of an electrical circuit model;
determine a target inductance of an inductive tuning element to compensate parasitic capacitance of a pad of the electrical circuit model by analyzing and tuning the extracted electrical circuit model using a lumped element; and
perform sensitivity analysis on a trace structure implementing the target inductance.

11. The system of claim 10, wherein the computer-executable instructions further cause the at least one physical processor to:
perform sensitivity analysis on an additional trace structure implementing the target inductance.

12. The system of claim 10, wherein the inductive tuning element corresponds to the trace structure and has a length selected to cause the trace structure to exhibit the target inductance.

13. The system of claim 10, wherein the inductive tuning element corresponds to a length of wire.

14. The system of claim 10, wherein the inductive tuning element is embedded in at least one of a land grid array package or a printed circuit board.

15. The system of claim 14, wherein the inductive tuning element is embedded in the land grid array package and a socket of the land grid array package has the inductive tuning element instead of a pin.

16. A computer-implemented method comprising:
performing, by at least one processor, model extraction of an electrical circuit model;
determining, by the at least one processor, a target inductance of an inductive tuning element to compensate parasitic capacitance of a pad of the electrical circuit model by analyzing and tuning the extracted electrical circuit model using a lumped element; and
performing, by the at least one processor, sensitivity analysis on a trace structure implementing the target inductance.

17. The computer-implemented method of claim 16, further comprising:
performing, by the at least one processor, sensitivity analysis on an additional trace structure implementing the target inductance.

18. The computer-implemented method of claim 16, wherein the inductive tuning element corresponds to the trace structure and has a length selected to cause the trace structure to exhibit the target inductance.

19. The computer-implemented method of claim 16, wherein the inductive tuning element corresponds to a length of wire.

20. The computer-implemented method of claim 16, wherein the inductive tuning element is embedded in at least one of a land grid array package or a printed circuit board.
